(19) United States
(12) Patent Application Publication
(10) Pub. No.: US 2026/0206219 A1
(43) Pub. Date: Jul. 16, 2026

(54) NON-VOLATILE MEMORY AND METHOD OF FABRICATING THE SAME

(71) Applicant: Powerchip Semiconductor Manufacturing Corporation, Hsinchu (TW)

(72) Inventors: Chien-Lin Chen, Hsinchu (TW); Hiroshi Yoshida, Hsinchu City (TW); Cheng-Yuan Hsu, Hsinchu City (TW)

(73) Assignee: Powerchip Semiconductor Manufacturing Corporation, Hsinchu (TW)

(21) Appl. No.: 19/049,003

(22) Filed: Feb. 10, 2025

(30) Foreign Application Priority Data
Jan. 13, 2025 (TW) 114101267

(51) Int. Cl. H10B 41/30; H10D 30/01; H10D 30/67; H10D 30/68

(52) U.S. Cl. CPC H10B 41/30; H10D 30/0411; H10D 30/6755; H10D 30/683; H10D 30/6892

(57) ABSTRACT

A non-volatile memory and a method of fabricating the same are provided. The non-volatile memory comprises a substrate; an oxide semiconductor layer on the substrate; a tunnel dielectric layer on the oxide semiconductor; a first gate stack on the tunnel dielectric layer; an erase gate on the tunnel dielectric layer; a second intergate dielectric layer between the first gate stack and the erase gate; and a source region and a drain region on the substrate and on opposite two sides of the oxide semiconductor layer. The first gate stack comprises: a floating gate on the tunnel dielectric layer; a first intergate dielectric layer on the floating gate; and a control gate on the first intergate dielectric layer.

### CROSS-REFERENCE TO RELATED APPLICATION

This application claims the priority benefit of Taiwan application serial no. 114101267, filed on Jan. 13, 2025. The entirety of the foregoing patent application is hereby incorporated by reference herein and made a part of this specification.

### TECHNICAL FIELD

The disclosure relates to a non-volatile memory, and in particular, to a non-volatile memory and a method of manufacturing the same.

### BACKGROUND

With the widespread popularity and the maturity of process technology of consumer electronics, such as smartphones, memory cards and flash drives, the application of the non-volatile memory, such as flash RAM, read-only memory (ROM), erasable programmable read-only memory (EPROM), electronically-erasable programmable read-only memory (EEPROM), etc., has grown significantly.

However, as the demand for various electronic products becomes more and more and there are higher requirements for the reading speed and the writing speed of non-volatile memory, it is also expected that the leakage current of non-volatile memory may also be reduced.

### SUMMARY

The disclosure provides a non-volatile memory and a method of fabricating the same, so as to increase the reading speed and the writing speed of the non-volatile memory and reduce its leakage current at the same time.

The disclosure provides a non-volatile memory, comprising: a substrate; an oxide semiconductor layer on the substrate; a tunnel dielectric layer on the oxide semiconductor layer; a gate stack on the tunnel dielectric layer, wherein the gate stack comprises: a floating gate on the tunnel dielectric layer, a first intergate dielectric layer on the floating gate, and a control gate on the first intergate dielectric layer; an erase gate on the tunnel dielectric layer; a second intergate dielectric layer between the gate stack and the erase gate; and a source region and a drain region on the substrate and on opposite sides of the oxide semiconductor layer.

According to an embodiment of the disclosure, the oxide semiconductor layer comprise In—Sn—Ga—Zn—O, In—Ga—Zn—O, In—Sn—Zn—O, In—Al—Zn—O, Sn—Ga—Zn—O, Al—Ga—Zn—O, Sn—Al—Zn—O, In—Zn—O, Sn—Zn—O, Al—Zn—O, Zn—Mg—O, Sn—Mg—O, In—Mg—O, In—O, Sn—O or Zn—O.

According to an embodiment of the disclosure, the oxide semiconductor layer comprise a material represented by the chemical formula InMO₃(ZnO)ₘ, wherein M is one or more selected from Ga, Al, Mn and Co, and m>0.

According to an embodiment of the disclosure, a thickness of the oxide semiconductor layer is 2 nm~200 nm.

According to an embodiment of the disclosure, the oxide semiconductor layer is a channel layer of the non-volatile memory.

According to an embodiment of the disclosure, the disclosure further comprises: a first spacer on the sidewall of the gate stack; and a second spacer on the sidewall of the erase gate.

According to an embodiment of the disclosure, a top surface of the control gate and a top surface of the erase gate are coplanar.

The disclosure proposes a method of fabricating non-volatile memory, which comprises providing a semiconductor substrate; forming an oxide semiconductor layer on the substrate; forming a tunnel dielectric layer on the oxide semiconductor layer; forming a gate stack on the tunnel dielectric layer, wherein the gate stack comprises: a floating gate on the tunnel dielectric layer, a first intergate dielectric layer on the floating gate, and a control gate on the first intergate dielectric layer; forming an erase gate on the tunnel dielectric layer; forming a second intergate dielectric layer between the gate stack and the erase gate; and forming a source region and a drain region on the substrate and on opposite sides of the oxide semiconductor layer.

According to an embodiment of the disclosure, the step of forming the oxide semiconductor layer on the substrate comprises: depositing an oxide semiconductor material on the substrate; and patterning the oxide semiconductor material to define the oxide semiconductor layer.

According to an embodiment of the disclosure, the step of depositing the oxide semiconductor material on the substrate comprises a physical vapor deposition (PVD), a chemical vapor deposition (CVD) or an atomic layer deposition (ALD).

According to an embodiment of the disclosure, the oxide semiconductor layer comprise In—Sn—Ga—Zn—O, In—Ga—Zn—O, In—Sn—Zn—O, In—Al—Zn—O, Sn—Ga—Zn—O, Al—Ga—Zn—O, Sn—Al—Zn—O, In—Zn—O, Sn—Zn—O, Al—Zn—O, Zn—Mg—O, Sn—Mg—O, In—Mg—O, In—O, Sn—O or Zn—O.

According to an embodiment of the disclosure, the oxide semiconductor layer comprises material represented by the chemical formula InMO₃(ZnO)ₘ, wherein M is one or more selected from Ga, Al, Mn and Co, and m>0.

According to an embodiment of the disclosure, a thickness of the oxide semiconductor layer is 2 nm~200 nm.

According to an embodiment of the disclosure, the oxide semiconductor layer is a channel layer of the non-volatile memory.

According to an embodiment of the disclosure, the method further includes: forming a first spacer on the sidewall of the gate stack; and forming a second spacer on the sidewall of the erase gate.

According to an embodiment of the disclosure, a top surface of the control gate and a top surface of the erase gate are coplanar.

Based on above, in the non-volatile memory and the method of manufacturing the same of the disclosure, the oxide semiconductor layer is used as the channel layer. Due to the characteristics of the material of the oxide semiconductor layer itself, the electrons in the non-volatile memory may have a higher mobility rate. Therefore, the reading speed and the writing speed of the non-volatile memory may be increased. In addition, using the oxide semiconductor layer as the channel layer of the non-volatile memory may also reduce leakage current and improve device efficiency.

In order to make the above-mentioned features and advantages of the disclosure more obvious and easy to understand, the embodiments are given below and described in detail with reference to the accompanying drawings.

### BRIEF DESCRIPTION OF THE DRAWINGS

FIG. 1 to FIG. 10 are flow sectional views of a method of fabricating non-volatile memory according to an embodiment of the disclosure,

### DESCRIPTION OF THE EMBODIMENTS

Embodiments are listed below and described in detail with reference to the drawings. However, the provided embodiments are not intended to limit the scope of the disclosure.

In order to the better understanding, the same elements will be described with the same symbols in the following description, and will not be repeated one by one in the following paragraphs.

In addition, the drawings are for illustrative purposes only and are not drawn to original size. In fact, the dimensions of the various features may be arbitrarily increased or reduced for clarity of discussion.

In addition, for the ease of description, the spatially relative terms such as “upper”, “lower” and their similar terms used in this description is used to describe the relative relationship between one element and another element as shown in the drawings, not to limit the disclosure. Therefore, it will be understood that “on” may be used interchangeably with “under” and that when a element is “on” another element, it may be placed directly on the other element, or intervening elements may be present. On the other hand, when an element is said to be placed “directly on” another element, there are no intervening element between the two.

The terminology used herein is used only to describe illustrative embodiments and does not limit the disclosure. The singular form includes the plural form unless the context dictates otherwise.

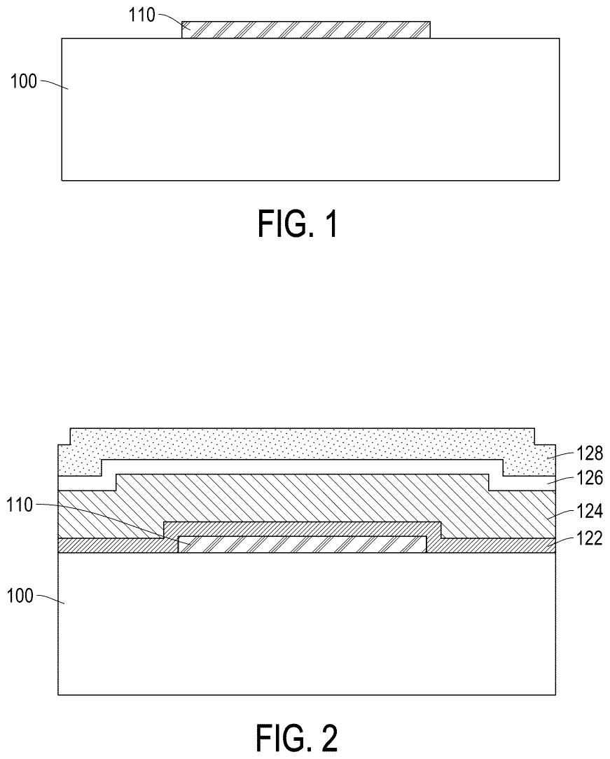

Please refer to FIG. 1, a substrate 100 is provided first, and then the oxide semiconductor layer 110 is formed on the substrate 100.

In some embodiments, the substrate 100 may include materials such as silicon and glass, but is not limited thereto. Any substrate 100 used to manufacture the non-volatile memory 10 may be used.

In some embodiments, the oxide semiconductor layer 110 may include a metal oxide, for example, quaternary metal oxides such as In—Sn—Ga—Zn—O; ternary metal oxides such as In—Ga—Zn—O, In—Sn—Zn—O, In—Al—Zn—O, Sn—Ga—Zn—O, Al—Ga—Zn—O, Sn—Al—Zn—O; binary metal oxides such as In—Zn—O, Sn—Zn—O, Al—Zn—O, Zn—Mg—O, Sn—Mg—O, In—Mg—O; monometallic oxides such as In—O, Sn—O, Zn—O, etc.

In addition, the oxide semiconductor layer 110 may include a material represented by the chemical formula InMO₃(ZnO)ₘ, wherein M is one or more metal elements selected from Ga, Al, Mn and Co. For example, M may be Ga alone, or a combination of two elements of Ga and Al, Ga and Mn, Ga and Co, etc. And m of the chemical formula InMO₃(ZnO)ₘ is >0.

In addition, among the materials represented by InMO₃(ZnO)ₘ (m>0), the material in which M is Ga is often called IGZO (Indium Gallium Zinc Oxide).

In some embodiments, the oxide semiconductor material may be formed on the substrate 100 using various suitable deposition methods, such as a physical vapor deposition (PVD), a chemical vapor deposition (CVD) or an atomic layer. Deposition (ALD) and other methods, but are not limited thereto. Any method that may be used to form oxide semiconductor materials may be used in the disclosure. Patterning is then performed by methods such as photolithography and etching, so that the required cell area and shape are defined on the oxide semiconductor layer 110.

The defined cell size and shape of the oxide semiconductor layer 110 must be able to accommodate the subsequently formed main devices of the non-volatile memory 10, such as the floating gate FG, the control gate CG, and the erase gate EG. However, the device density also needs to be taken into consideration and cannot be expanded without limit.

In addition, the thickness of the formed oxide semiconductor layer 110 also varies depending on factors such as the material of the oxide semiconductor layer 110 used and the size of the non-volatile memory 10 to be formed. Generally speaking, the thickness of the formed oxide semiconductor layer 110 may be about 2 nm to 200 nm, preferably 2 nm to 5 nm. But this thickness range is consistent with the size of the current non-volatile memory 10. As a result of matching, as the size of the non-volatile memory 10 changes in the future, the thickness of the oxide semiconductor layer 110 must also change accordingly.

The oxide semiconductor layer 110 may be used as a channel layer of the non-volatile memory 10 as shown in FIG. 10. Due to the characteristics of the material of the oxide semiconductor layer 110 itself, the electrons in the non-volatile memory 10 may have higher mobility rate. Therefore, the reading speed and the writing speed of the non-volatile memory 10 may be increased; in addition, using the oxide semiconductor layer 110 as the channel layer of the non-volatile memory 10 may also reduce leakage current and improve device efficiency.

Next, referring to FIG. 2, a tunnel dielectric layer 122 is formed on the oxide semiconductor layer 110.

In some embodiments, the tunnel dielectric layer 122 may include an oxide layer, but is not limited thereto.

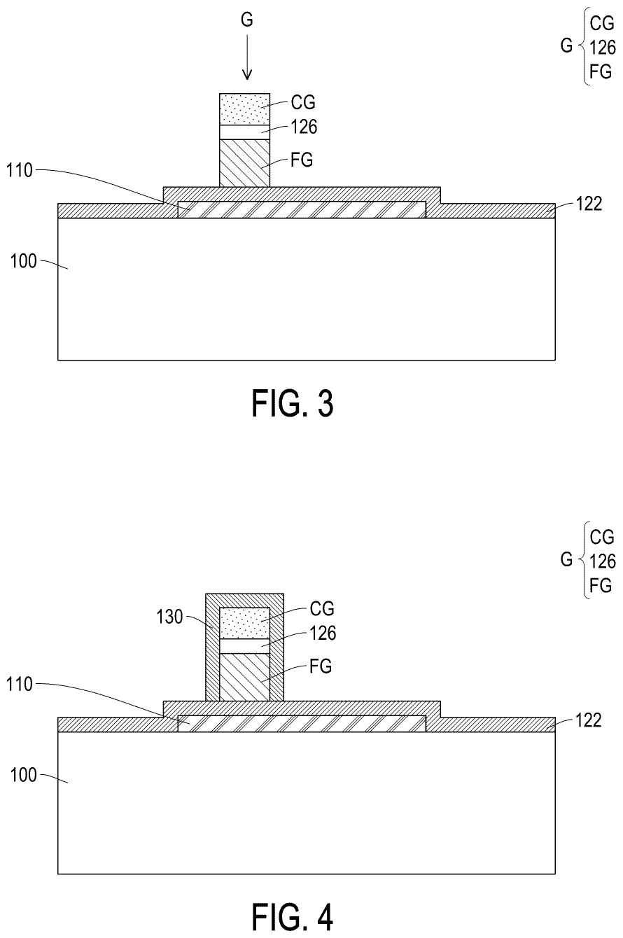

Next, please refer to FIG. 2 and FIG. 3 at the same time. The gate stack G is formed on the tunnel dielectric layer 122, wherein the gate stack G includes a floating gate FG on the tunnel dielectric layer 122, a first intergate dielectric layer 126 on the floating gate FG, and a control gate on the first intergate dielectric layer 126.

In some embodiments, the above-mentioned step of forming the gate stack G on the tunnel dielectric layer 122 may include the following steps: forming sequentially the electron access layer 124, the dielectric layer 126 and the first polysilicon layer 128 on the tunnel dielectric layer 122, as shown in FIG. 2; next, by photolithography and etching, patterning the first polycrystalline silicon layer 128, the dielectric layer 126 and the electron access layer 124, so as to sequentially form the control gate CG, the first intergate dielectric layer 126 and the floating gate FG and to complete the definition of the gate stack G, as shown in FIG. 3.

In some embodiments, the electron access layer 124 may include any electron access material suitable for the non-volatile memory 10 to be used as the floating gate FG of the non-volatile memory 10, such as silicon nitride (Si₃N₄) material or polycrystalline silicon material, but is not limited thereto.

The dielectric layer 126 may include any suitable material between the floating gate FG and the control gate CG of the non-volatile memory 10, to make the non-volatile memory 10 with smaller leakage current and better data saving capability, so that the reliability of the non-volatile memory 10 may be improved. In some embodiments, the dielectric layer 126 may include an oxide layer, a nitride layer, or a combination of multiple oxide layers and nitride layers, such as Oxide-Nitride-Oxide (ONO) layer or Oxide-Nitride-Oxide-Nitride (ONON) layer.

The first polysilicon layer 128 forms the control gate CG of the non-volatile memory 10 after the definition of cell of the gate stack G.

Next, as shown in FIG. 4, a first oxide layer 130 may be formed on the top surface and side surfaces of the gate stack G by deposition or tempering.

Then, a second polysilicon layer 140 is deposited on the tunnel dielectric layer 122 and the gate stack G.

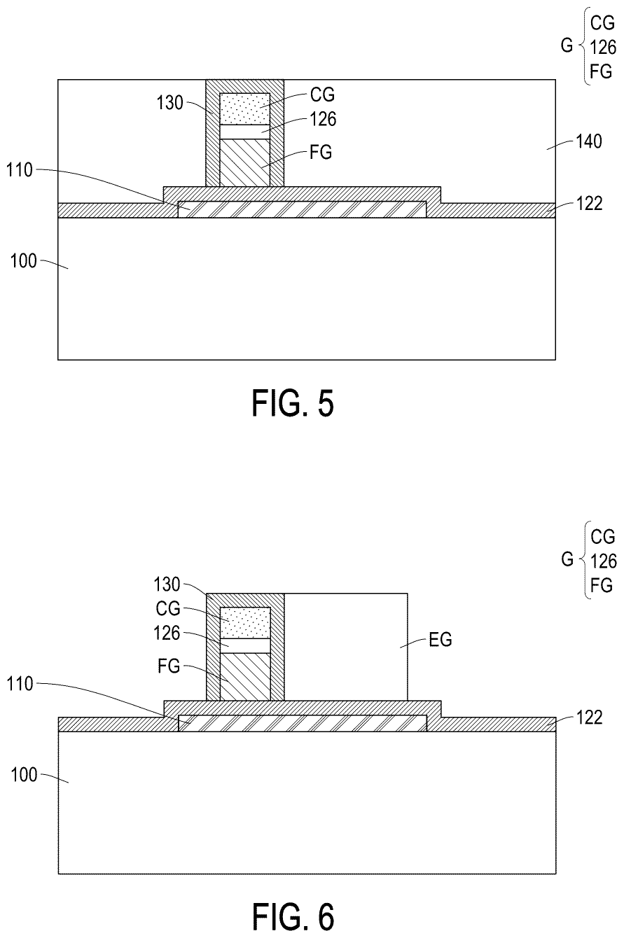

In some embodiments, the second polycrystalline silicon layer 140 may completely cover the gate stack G, that is, the thickness of the deposited second polycrystalline silicon layer 140 may exceed the thickness of the gate stack G. Then, the comprehensive planarization method, such as chemical mechanical polishing (CMP), is used to remove the excess second polycrystalline silicon layer 140 in the vertical direction. And since there is a certain degree of etching selectivity between the polycrystalline silicon and the oxide layer, the removal of the second polycrystalline silicon layer 140 may be stopped at a level coplanar with the top surface of the first oxide layer 130. That is, at this time, a top surface of the first oxide layer 130 and a top surface of second polycrystalline silicon layer 140 are coplanar, as shown in FIG. 5.

Next, the second polysilicon layer 140 is patterned by photolithography and etching to define the size of the erase gate EG of the non-volatile memory 10 on the tunnel dielectric layer 122, as shown in FIG. 6 shown.

Next, a second oxide layer 150 may be formed on the top and sidewalls of the erase gate EG by direct deposition or thermal oxidation.

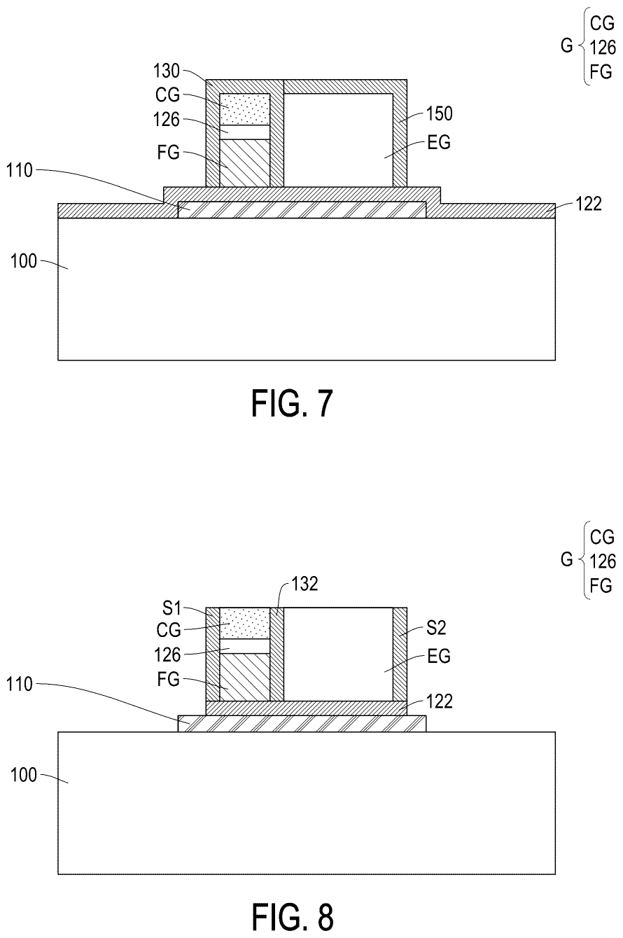

If the second oxide layer 150 is formed on the top and sidewalls of the erase gate EG by thermal oxidation, since the erase gate EG is formed by patterning the second polycrystalline silicon layer 140, in an environment full of oxygen and high temperature, the polycrystalline silicon exposed to the oxygen environment will be oxidized into silicon oxide. Therefore, shown as the erase gate EG of FIG. 6, the outer part of the erase gate EG exposed to the oxygen environment is thermally oxidized. Therefore, the erase gate EG made of polycrystalline silicon will shrink inward to the erase gate EG, shown as FIG. 7, and the exposed top and the sidewall of the erase gate EG shown in FIG. 6 forms the second oxide layer 150. The degree of shrinkage of the erase gate EG is not as obvious as shown in FIG. 7. This exaggerated illustration is for a clearer description and illustration.

Next, as shown in FIG. 8, various etching methods may be used to remove the exposed tunnel dielectric layer 122, the first oxide layer 130 on the top surface of the gate stack G, and the second oxide layer 150 on the top surface of the erase gate EG, to expose a part of the top surface of the substrate 100, the top surface of the control gate CG and the top surface of the erase gate EG.

The first oxide layer 130 remaining after the etching process is formed as a first partition S1 on the sidewall of the gate stack G and a second intergate dielectric layer 132 between the gate stack G and the erase gate EG. Furthermore, the second oxide layer 150 remaining after the etching process is formed as a second partition S2 on the sidewall of the erased gate EG.

In some embodiments, dry etching may be used to remove the exposed tunnel dielectric layer 122, the first oxide layer 130 on the top surface of the gate stack G and the second oxide layer 150 on the top surface of the gate electrode EG, to expose a part of the top surface of the substrate 100, the top surface of the control gate CG and the top surface of the erase gate EG. So that the first oxide layer 130 remaining after the etching process is formed as the first spacer S1 on the sidewall of the gate stack G and the second intergate dielectric layer 132 between the gate stack G and the erase gate EG. Furthermore, the second oxide layer 150 remaining after the etching process is formed as a second partition S2 on the sidewall of the erased gate EG.

In some embodiments, wet etching may also be used to remove the exposed tunnel dielectric layer 122, the first oxide layer 130 on the top surface of the gate stack G and the second oxide layer 150 on the top surface of the gate electrode EG, to expose a part of the top surface of the substrate 100, the top surface of the control gate CG and the top surface of the erase gate EG. So that the first oxide layer 130 remaining after the etching process is formed as the first spacer S1 on the sidewall of the gate stack G and the second intergate dielectric layer 132 between the gate stack G and the erase gate EG. Furthermore, the second oxide layer 150 remaining after the etching process is formed as a second partition S2 on the sidewall of the erased gate EG. Especially when the tunnel dielectric layer 122 is an oxide, since the tunnel dielectric layer 122, the first oxide layer 130 and the second oxide layer 150 to be removed are all oxides, there is the relatively high etching selectivity relative to the oxide semiconductor layer 110. Therefore, the damage of the oxide semiconductor layer 110 serving as the channel layer during the wet etching process may be avoided.

In some embodiments, the top surface of the control gate CG and the top surface of the erase gate EG may be coplanar, as shown in FIG. 8.

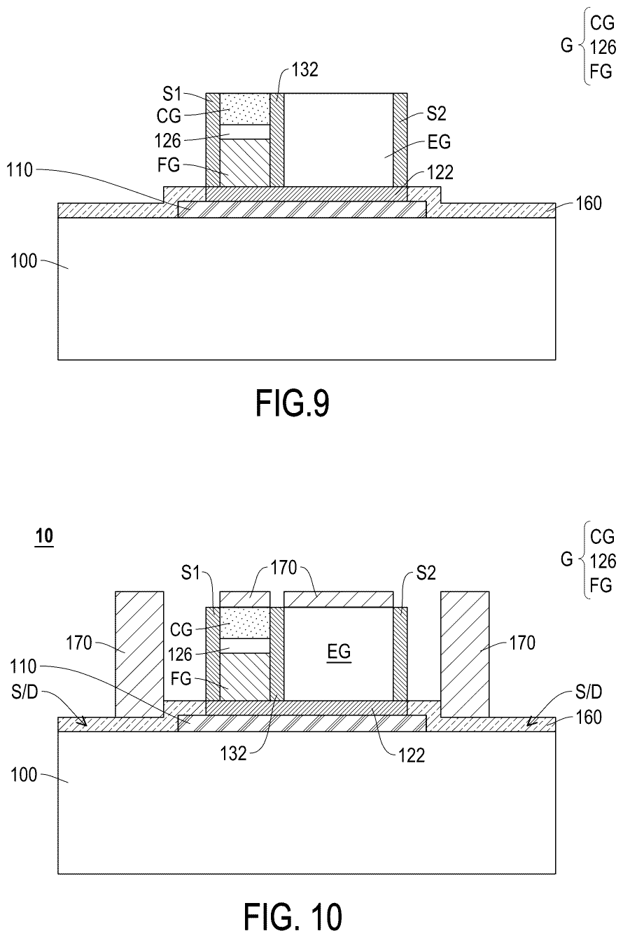

Next, as shown in FIG. 9, a conductive layer 160 may be formed on the substrate 100. The conductive layer 160 may include a conductive material such as titanium nitride (TiN) to reduce the resistance between the subsequent formed contact plug 170 and the substrate 100.

Then, as shown in FIG. 10, a source region and a drain region S/D are formed on the substrate 100 and on opposite sides of the oxide semiconductor layer 110. A plurality of contact plugs 170 are formed on the conductive layer 160, the top surface of the control gate CG and the top surface of the erase gate EG, to facilitate the control of the device. An insulating materials such as silicon oxide (not shown) are further included between the contact plugs 170.

In the non-volatile memory 10 in the embodiment of the disclosure, the oxide semiconductor layer 110 may be used as a channel layer of the non-volatile memory 10 as shown in FIG. 10. Due to the characteristics of the material of the oxide semiconductor layer 110 itself, the electrons in the non-volatile memory 10 may have higher mobility rate. Therefore, the reading speed and the writing speed of the non-volatile memory 10 may be increased; in addition, using the oxide semiconductor layer 110 as the channel layer of the non-volatile memory 10 may also reduce leakage current and improve device efficiency.

Based on above, in the non-volatile memory and the method of manufacturing the same of the disclosure, the oxide semiconductor layer is used as the channel layer. Due to the characteristics of the material of the oxide semiconductor layer itself, the electrons in the non-volatile memory may have a higher mobility rate. Therefore, the reading speed and the writing speed of the non-volatile memory may be increased. In addition, using the oxide semiconductor layer as the channel layer of the non-volatile memory may also reduce leakage current and improve device efficiency.

Although the disclosure has been disclosed above through embodiments, they are not intended to limit the disclosure. Any person with ordinary knowledge in the relevant technical field may make some modifications and changes without departing from the spirit and scope of the disclosure. Therefore, the claimed scope of the disclosure shall be determined by the claims of the claims.

What is claimed is:

1. A non-volatile memory, comprising:
a substrate;
an oxide semiconductor layer on the substrate;
a tunnel dielectric layer on the oxide semiconductor layer;
a gate stack on the tunnel dielectric layer, wherein the gate stack comprises:
a floating gate on the tunnel dielectric layer,
a first intergate dielectric layer on the floating gate, and
a control gate on the first intergate dielectric layer;
an erase gate on the tunnel dielectric layer;
a second intergate dielectric layer between the gate stack and the erase gate; and
a source region and a drain region on the substrate and on opposite sides of the oxide semiconductor layer.

2. The non-volatile memory according to claim 1, wherein the oxide semiconductor layer comprises In—Sn—Ga—Zn—O, In—Ga—Zn—O, In—Sn—Zn—O, In—Al—Zn—O, Sn—Ga—Zn—O, Al—Ga—Zn—O, Sn—Al—Zn—O, In—Zn—O, Sn—Zn—O, Al—Zn—O, Zn—Mg—O, Sn—Mg—O, In—Mg—O, In—O, Sn—O or Zn—O.

3. The non-volatile memory according to claim 1, wherein the oxide semiconductor layer comprises a material represented by a chemical formula InMO₃(ZnO)ₘ, wherein M is one or more selected from Ga, Al, Mn and Co, and m>0.

4. The non-volatile memory according to claim 1, wherein a thickness of the oxide semiconductor layer is 2 nm~200 nm.

5. The non-volatile memory according to claim 1, wherein the oxide semiconductor layer is a channel layer of the non-volatile memory.

6. The non-volatile memory according to claim 1, further comprising:
a first spacer on a sidewall of the gate stack; and
a second spacer on a sidewall of the erase gate.

7. The non-volatile memory of claim 1, wherein a top surface of the control gate and a top surface of the erase gate are coplanar.

8. A method of fabricating non-volatile memory, comprising:
providing a substrate;
forming an oxide semiconductor layer on the substrate;
forming a tunnel dielectric layer on the oxide semiconductor layer;
forming a gate stack on the tunnel dielectric layer, wherein the gate stack comprises:
a floating gate on the tunnel dielectric layer,
a first intergate dielectric layer is on the floating gate, and
a control gate on the first intergate dielectric layer;
forming an erase gate on the tunnel dielectric layer;
forming a second intergate dielectric layer between the gate stack and the erase gate; and
forming a source region and a drain region on the substrate and on opposite sides of the oxide semiconductor layer.

9. The method of fabricating non-volatile memory according to claim 8, wherein the step of forming the oxide semiconductor layer on the substrate comprises:
depositing an oxide semiconductor material on the substrate; and
patterning the oxide semiconductor material to define the oxide semiconductor layer.

10. The manufacturing method of non-volatile memory according to claim 9, the step of depositing the oxide semiconductor material on the substrate comprises a physical vapor deposition (PVD), a chemical vapor deposition (CVD) or an atomic layer deposition (ALD).

11. The method of fabricating non-volatile memory according to claim 8, wherein the oxide semiconductor layer comprises In—Sn—Ga—Zn—O, In—Ga—Zn—O, In—Sn—Zn—O, In—Al—Zn—O, Sn—Ga—Zn—O, Al—Ga—Zn—O, Sn—Al—Zn—O, In—Zn—O, Sn—Zn—O, Al—Zn—O, Zn—Mg—O, Sn—Mg—O, In—Mg—O, In—O, Sn—O or Zn—O.

12. The method of fabricating non-volatile memory according to claim 8, wherein the oxide semiconductor layer comprises a material represented by the chemical formula InMO₃(ZnO)ₘ, wherein M is one or more selected from Ga, Al, Mn and Co, and m>0.

13. The manufacturing method of the non-volatile memory according to claim 8, wherein a thickness of the oxide semiconductor layer is 2 nm~200 nm.

14. The method of fabricating non-volatile memory according to claim 8, wherein the oxide semiconductor layer is a channel layer of the non-volatile memory.

15. The method of fabricating non-volatile memory according to claim 8, further comprising:
forming a first spacer on a sidewall of the gate stack; and
forming a second spacer on a sidewall of the erase gate.

16. The method of fabricating non-volatile memory according to claim 8, wherein a top surface of the control gate and a top surface of the erase gate are coplanar.
